(19) United States
(12) Patent Application Publication
(10) Pub. No.: US 2003/0148021 A1
(43) Pub. Date: Aug. 7, 2003

(54) Manufacturing apparatus and method for manufacturing an organic electroluminescence panel

(75) Inventor: Shinichi Ishizuka, Tsurugashima-shi (JP)

Correspondence Address: MORGAN LEWIS & BOCKIUS LLP, 1111 PENNSYLVANIA AVENUE NW, WASHINGTON, DC, 20004, US

(73) Assignee: PIONEER CORPORATION

(21) Appl. No.: 10/352,996

(22) Filed: Jan. 29, 2003

(30) Foreign Application Priority Data
Feb. 1, 2002 (JP) 2002-25691

(51) Int. Cl. B05D 5/12; B05D 5/06

(52) U.S. Cl. 427/66; 118/724

(57) ABSTRACT

A manufacturing apparatus for manufacturing an organic EL display panel, includes a thermal head having a heating region covering at least part of a display region to be constituted by a plurality of organic EL elements to be formed on the substrate, with a space maintained between the display region and the heating region. The organic EL display panel has a plurality of organic EL elements arranged on a substrate, each of the organic EL elements being formed of at least one organic layer each of which contains a light-emitting layer sandwiched by a pair of electrodes. The apparatus also includes a deposition material sheet formed of a heat-resistant sheet having one main surface thereof coated with a thin layer of a deposition material and another main surface thereof in contact with thermal head, and a support mechanism for causing the thin layer on the deposition material sheet and the substrate to be opposed to each other with a space maintained therebetween.

### BACKGROUND OF THE INVENTION

1. Field of the Invention

The present invention relates to a manufacturing apparatus and method for manufacturing an organic electroluminescence panel having a plurality of organic electroluminescence elements formed on a display panel substrate in a predetermined pattern, in which each of the organic electroluminescence elements has a light-emitting layer formed of a thin layer of an organic compound material exhibiting electroluminescence, i.e., the phenomenon of emission of light in response to injection of electric current (hereinafter also referred to as “EL”). Furthermore this invention relates particularly to a vacuum deposition apparatus used for the manufacturing apparatus and method for manufacturing the same.

2. Description of the Related Art

An organic EL element is comprised, for example, of a transparent electrode, one or more thin layers including a light-emitting layer made of an organic compound or more (hereinafter also referred to as “organic layer”), and a metal electrode, which are sequentially deposited on a transparent substrate. For instance, the organic layer may be in the form of a single light-emitting layer, or have a three-layered structure having an organic hole transport layer, a light-emitting layer, and an organic electron transport layer, or a two-layered structure having an organic hole transport layer and a light-emitting layer. Further, the organic layer may be a laminate constructed by forming an electron or hole injection layer between suitable layers of the above-mentioned layers.

An organic EL display panel, for example, of a matrix type is comprised of layers of row electrodes including a transparent electrode layer, an organic layer, and column electrodes including a metal electrode layer and arranged crosswise to the row electrodes, which are sequentially deposited one upon another. The row electrodes are in the form of strips arranged in parallel with each other at predetermined spaced intervals, and the column electrodes are also formed in a similar arrangement. Thus, the matrix type display panel has a display region comprised of a plurality of organic EL elements (i.e., light-emitting pixels) formed at respective intersections of the row electrodes and the column electrodes, in a matrix-like arrangement. The organic EL elements in the display region are arranged in matrix and connected on an as-needed basis to be driven by predetermined signals, whereby an image can be displayed. Further, if a display region comprised of organic EL elements emitting three primary color lights of red R, green G, and blue B is formed, a full color display apparatus can be constructed.

In the manufacturing process of the organic EL display panel, the transparent electrode layer is formed on the transparent substrate, and then the organic layers are formed.

In a conventional vacuum deposition method, as shown in

FIG. 1, by using a vacuum deposition apparatus 1, a deposition material 2, such as an organic material or an electrode material, is placed in a boat 3 and heated, and the vapor of the deposition material 2 is deposited on a glass substrate 4 arranged several tens of centimeters away from the boat 3, or as shown in the figure, a metal mask 5 is used for selective formation of a layer of the organic material or a layer of the electrode material.

In manufacturing a small-sized display panel, the productivity of the manufacturing process using the deposition method is enhanced by forming a plurality of small display panel substrates from a single large transparent board.

When the large transparent board is used, the deposition process necessitates the use of a large mask having a plurality of mask areas (multi-panel forming large mask) formed by openings corresponding to a plurality of display regions of small-sized display panels, respectively.

However, due to the use of the multi-panel forming large mask, even if only one of the plurality of metal mask areas has a defect, such as dimensional inaccuracy, this causes a considerable lowering of the manufacturing yield of display panels.

Further, in the vacuum deposition apparatus using the vacuum deposition method, it is required to keep a distance between an evaporation source and a display panel substrate to ensure uniformity of layers deposited on the substrate, and hence the size of the manufacturing apparatus is inevitably increased, which causes an increase in manufacturing costs. Moreover, due to the large distance between the evaporation source and the display panel substrate, the use efficiency of a material is degraded, and deposition of a layer takes a long time.

### OBJECT AND SUMMARY OF THE INVENTION

The present invention has been made in view of the above situation and an object thereof is to provide an apparatus and method for manufacturing an organic EL display panel, which makes it possible to reduce the size of a manufacturing apparatus and manufacturing costs.

According to a first aspect of the invention, there is provided a manufacturing apparatus for manufacturing an organic EL display panel that has a plurality of organic EL elements arranged on a substrate, each of the organic EL elements being formed of at least one organic layer each of which contains a light-emitting layer sandwiched by a pair of electrodes,

the manufacturing apparatus comprising:

one or more heating elements having a heating region covering at least part of a display region to be constituted by a plurality of organic EL elements to be formed on the substrate, with a space maintained between the display region and the heating region;

a deposition material sheet formed of a heat-resistant sheet having one main surface thereof coated with a thin layer of a deposition material and another main surface thereof in contact with the heating elements; and

a support mechanism for causing the thin layer on the deposition material sheet and the substrate to be opposed to each other with a space maintained therebetween.

In the manufacturing apparatus according to the invention, said heating region has an area covering substantially said display region.

In the manufacturing apparatus according to the invention, said heating region has a width smaller than that of said display region so as to extend over said display region and having an area smaller than that of said display region.

The manufacturing apparatus according to the invention may further comprises at least one active device connected to said organic EL element and formed on said substrate.

In the manufacturing apparatus according to the invention, said heating region is constituted by a plurality of heating elements corresponding to said organic EL elements to be formed.

In the manufacturing apparatus according to the invention, said heating elements are arranged one-dimensionally.

In the manufacturing apparatus according to the invention, said heating elements are arranged two-dimensionally.

In the manufacturing apparatus according to the invention, said heating elements are in a one-to-one correspondence with said light-emitting portions.

In the manufacturing apparatus according to the invention, said heating elements and said organic EL elements to be formed are arranged at intervals of an identical pitch.

In the manufacturing apparatus according to the invention, said heating elements are arranged at intervals of integer times of a pixel pitch of said organic EL elements to be formed.

In the manufacturing apparatus according to the invention, said heating elements are formed as protrusions.

The manufacturing apparatus according to the invention may further comprises a power unit connected to said heating elements for selectively energizing said heating elements to evaporate the deposition material.

The manufacturing apparatus according to the invention may further comprises a temperature control system connected to said heating elements for controlling the temperature of said heating elements.

In the manufacturing apparatus according to the invention, said temperature control system comprises a temperature-detecting section for detecting said heating elements so as to control the temperature of said heating elements according to the detected temperature.

In the manufacturing apparatus according to the invention, said temperature control system controls the temperature of said heating elements such that uniformity in temperature of said heating elements is maintained.

In the manufacturing apparatus according to the invention, said temperature control system controls the temperature of said heating elements such that individual temperature of said heating elements is differ from each other.

In the manufacturing apparatus according to the invention, said heating region is constituted by a single heating element corresponding to said organic EL elements to be formed.

In the manufacturing apparatus according to the invention, a power unit connected to said single heating element for energizing said heating element to evaporate the deposition material.

The manufacturing apparatus according to the invention may further comprises a temperature control system connected to said single heating element for controlling the temperature of said heating element.

In the manufacturing apparatus according to the invention, said temperature control system comprises a temperature-detecting section for detecting said single heating element so as to control the temperature of said heating element according to the detected temperature.

In the manufacturing apparatus according to the invention, the heating elements are placed below said substrate in a gravitation direction.

The manufacturing apparatus according to the invention may further comprises a translation drive apparatus for causing translation of said heating elements and said substrate relative to each other in parallel.

In the manufacturing apparatus according to the invention, said heating elements are grouped as plural sets and operated so that the deposition material is partly deposited on said substrate per set.

In the manufacturing apparatus according to the invention, said support mechanism comprising a support member formed on said substrate.

The manufacturing apparatus according to the invention may further comprises a metal mask having a plurality of openings corresponding to said organic EL elements and placed between said substrate and said deposition material sheet.

In the manufacturing apparatus according to the invention, the deposition material is an organic material or an electrode material.

According to a second aspect of the invention, there is provided a method of manufacturing an organic EL display panel that has a plurality of organic EL elements arranged on a substrate, each of the organic EL elements being formed of at least one organic layer each of which contains a light-emitting layer sandwiched by a pair of electrodes,

the method comprising the steps of:

positioning a deposition material sheet formed of a heat-resistant sheet having one main surface thereof coated with a thin layer of a deposition material such that another main surface of the deposition material sheet is brought into contact with one or more heating elements having a heating region corresponding to at least part of a display region to be constituted by a plurality of organic EL elements to be formed on the substrate;

causing the thin layer on the deposition material sheet and the substrate to be opposed to each other with a space maintained therebetween; and

heating the deposition material sheet by energizing the heating region, thereby evaporating the deposition material to form a layer thereof on the substrate.

In the manufacturing method according to the invention, said heating region has an area covering substantially said display region.

In the manufacturing method according to the invention, said heating region has a width smaller than that of said display region so as to extend over said display region and having an area smaller than that of said display region, and said method further comprising a step of vacuum deposition for partly depositing the deposition material on said substrate in a manner that said vacuum deposition is repeatedly preformed for said substrate.

In the manufacturing method according to the invention, said heating region is constituted by a plurality of heating elements corresponding to said organic EL elements to be formed.

In the manufacturing method according to the invention, said heating elements are arranged one-dimensionally.

In the manufacturing method according to the invention, said heating elements are arranged two-dimensionally.

In the manufacturing method according to the invention, said heating elements are in a one-to-one correspondence with said light-emitting portions.

In the manufacturing method according to the invention, said heating elements and said organic EL elements to be formed are arranged at intervals of an identical pitch.

In the manufacturing method according to the invention, said heating elements are arranged at intervals of integer times of a pixel pitch of said organic EL elements to be formed.

In the manufacturing method according to the invention, said heating elements are formed as protrusions.

The manufacturing method according to the invention may further comprises a step of selectively energizing and heating said heating elements to evaporate the deposition material.

In the manufacturing method according to the invention, said heating elements are detected in temperature so that the temperature of said heating elements are controlled according to the detected temperature.

In the manufacturing method according to the invention, temperature of said heating elements is controlled such that uniformity in temperature of said heating elements is maintained.

In the manufacturing method according to the invention, temperature of said heating elements is controlled such that individual temperature of said heating elements is different from each other.

In the manufacturing method according to the invention, said heating region is constituted by a single heating element corresponding to said organic EL elements to be formed.

In the manufacturing method according to the invention, said heating element is selectively energized and heated to evaporate the deposition material.

In the manufacturing method according to the invention, said heating element is detected in temperature so that the temperature of said heating element is controlled according to the detected temperature.

In the manufacturing method according to the invention, the heating elements are placed below said substrate in a gravitation direction.

In the manufacturing method according to the invention, said heating elements and said substrate are moves in translation relative to each other in parallel.

In the manufacturing method according to the invention, said heating elements are grouped as plural sets and operated so that the deposition material is partly deposited on said substrate per set.

The manufacturing method according to the invention may further comprises a step of forming a support member on said substrate to separate said deposition material sheet and said substrate with a space.

The manufacturing method according to the invention may further comprises a step of providing a metal mask having a plurality of openings corresponding to said organic EL elements and placed between said substrate and said deposition material sheet.

In the manufacturing method according to the invention, the deposition material is an organic material or an electrode material.

In the manufacturing method according to the invention, said step of evaporating the deposition material to perform deposition on the substrate, comprises a step of collectively depositing an organic material common to said organic EL elements for colors of light emission at an identical thickness, and steps of respectively depositing organic materials as layers having different thicknesses corresponding to colors of light emission of said organic EL elements.

In the manufacturing method according to the invention, said step of evaporating the deposition material to perform deposition on the substrate, comprises a step of collectively depositing an identical organic material common to said organic EL elements for colors of light emission, and steps of respectively depositing different organic materials corresponding to colors of light emission of said organic EL elements.

### BRIEF DESCRIPTION OF THE DRAWINGS

The aforementioned aspects and other features of the invention are explained in the following description, taken in connection with the accompanying drawing figures wherein:

FIG. 1 is a cross-sectional view schematically showing a conventional vacuum deposition apparatus;

FIG. 2 is a cross-sectional view schematically showing an organic EL display panel-manufacturing apparatus according to an embodiment of the invention;

FIG. 3 is a cross-sectional view schematically showing a deposition material sheet according to the embodiment;

FIG. 4 is a cross-sectional view schematically showing a thermal head according to an embodiment of the invention;

FIG. 5 is a cross-sectional view schematically showing a thermal head according to another embodiment of the invention;

FIG. 6 is a plan view of schematically showing a thermal head according to an embodiment of the invention;

FIG. 7 is a plan view schematically showing an example of a light-emitting pixel array on a full-color organic EL display panel;

FIG. 8 is a perspective view schematically showing part of the organic EL display panel;

FIG. 9 is a cross-sectional view schematically showing a display panel substrate according to the embodiment;

FIG. 10 is a cross-sectional view schematically showing a stacked state of a display panel substrate, a deposition material sheet and a thermal head in a step of the manufacturing method according to the embodiment of the invention;

FIG. 11 is a cross-sectional view schematically showing a relationship between a display panel substrate having an array of light-emitting portions and a thermal head in the embodiment according to the invention;

FIGS. 12 to 15 are cross-sectional views each schematically showing a stacked state of a display panel substrate, a deposition material sheet and a thermal head in a step of an organic EL display panel-manufacturing process according to an embodiment of the invention;

FIG. 16 is a cross-sectional view schematically showing a relationship between a display panel substrate having an array of light-emitting portions and a thermal head in another embodiment according to the invention;

FIGS. 17 to 19 are cross-sectional views each schematically showing a stacked state of a display panel substrate, a deposition material sheet and a thermal head in a step of an organic EL display panel-manufacturing process according to another embodiment of the invention;

FIG. 20 is a cross-sectional view schematically showing a stacked state of a display panel substrate, a deposition material sheet and a thermal head in a step of the manufacturing method according to another embodiment of the invention;

FIG. 21 is a plan view schematically showing a thermal head according to another embodiment of the invention;

FIG. 22 is a perspective view showing a stacked state of a display panel substrate, a deposition material sheet and the thermal head of FIG. 6 for explaining the organic EL display panel-manufacturing process according to the embodiment of the invention;

FIG. 23 is a perspective view showing a stacked state of a display panel substrate, a deposition material sheet and the thermal head of FIG. 21 for explaining the organic EL display panel-manufacturing process according to another embodiment of the invention;

FIGS. 24 and 25 are plan views useful in explaining respective organic EL display panel-manufacturing processes according to other embodiments;

FIG. 26 is a plan view schematically showing a thermal head according to another embodiment of the invention;

FIG. 27 is a perspective view showing a stacked state of a display panel substrate, a deposition material sheet and the thermal head of FIG. 26 for explaining the organic EL display panel-manufacturing process according to another embodiment of the invention;

FIG. 28 is a plan view schematically showing a thermal head according to another embodiment of the invention;

FIG. 29 is a perspective view showing a stacked state of a display panel substrate, a deposition material sheet and the thermal head of FIG. 28 for explaining the organic EL display panel-manufacturing process according to another embodiment of the invention; and

FIG. 30 is a cross-sectional view useful in explaining an organic EL display panel-manufacturing process according to another embodiment.

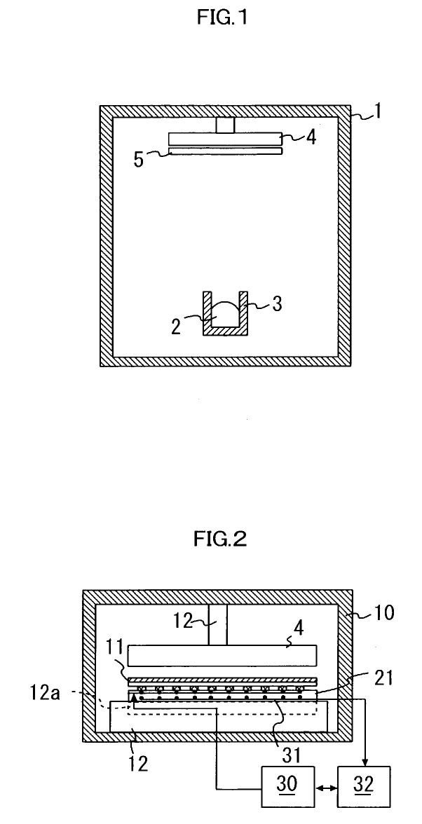

### DETAILED DESCRIPTION OF THE PREFERRED EMBODIMENTS

A device of an embodiment according to the present invention will be described below with reference to the drawings.

FIG. 2 shows an example of a manufacturing apparatus for manufacturing an organic EL display panel according to the invention.

Within a pressure-reduced growth chamber 10 of the organic EL display panel-manufacturing apparatus, a display panel substrate 4 (e.g., transparent substrate made of glass) and a thermal head 21 in contact with a deposition material sheet 11 are caused to be opposed to each other with a space therebetween by a support mechanism 12. The support mechanism 12 includes a translation drive apparatus 12a for causing translation of the thermal head 21 and the substrate 4 relative to each other. The thermal head 21 has a heating region formed by heating elements and covering a nearly entire display region to be constituted by a plurality of organic EL elements which are to be formed on the display panel substrate 4, so that when the thermal head 21 is energized to heat the deposition material sheet 11 in the state in contact with the sheet 11 and spaced from the substrate 4, the deposition material is evaporated and deposited on the substrate 4 to form a layer thereon as shown in FIG. 2. The manufacturing apparatus includes a power unit 30 connected to the heating elements of the thermal head 21, for selectively energizing the heating elements to evaporate the deposition material. Further, the manufacturing apparatus includes a temperature-detecting section 31 connected to the heating elements, for detecting the temperature thereof, and a temperature control section 32 connected to the power unit 30, for controlling the temperature of the heating elements according to the detected temperature. In the case of the thermal head 21 being constituted by a plurality of heating elements, for instance, the temperature control section 32 controls the power unit 30 such that uniformity in temperature of the heating elements is maintained. Further, the temperature control section 32 can also control the temperatures of the respective heating elements separately such that they differ from each other.

FIG. 3 shows an example of the deposition material sheet 11 in cross section. The deposition material sheet 11 is formed to have a predetermined thickness by vacuum deposition of a light-emitting organic compound 11b, for example, of tris (8-quinolinolato) aluminum onto one main surface of a heat-resistant sheet 11a formed, for example, of a metal, such as copper, or a plastic, which has a thickness of tens of micrometers. The thermal head 21 is positioned in contact with the other main surface of the deposition material sheet 11.

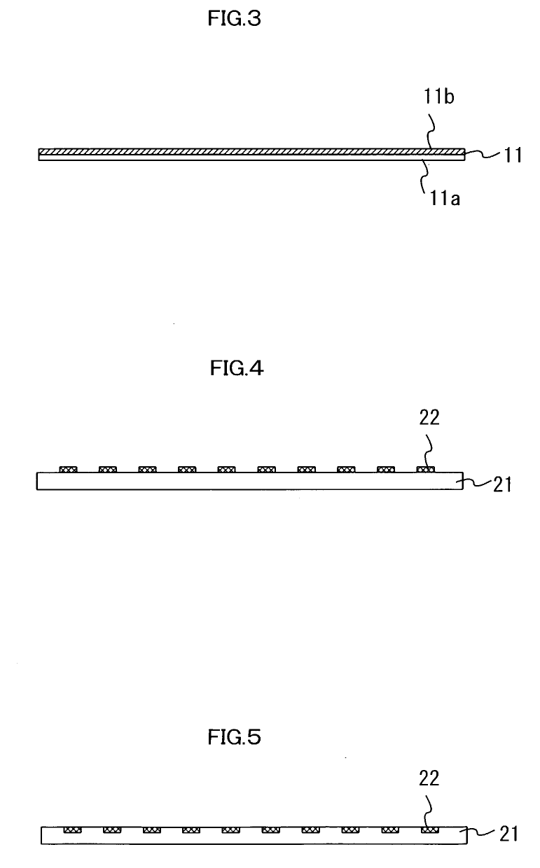

FIG. 4 shows an example of the thermal head 21 in cross section. The thermal head 21 has a plurality of heating elements 22 as protrusions corresponding to respective organic EL elements of an organic EL display panel to be formed. The use of the thermal head having the heating elements 22 protruding as shown in FIG. 4 makes it possible to apply heat more intensively to respective portions to be heated for evaporation and hence achieve selective deposition more reliably. It should be noted that the thermal head 21 may have a plurality of heating elements 22 embedded therein as shown in FIG. 5.

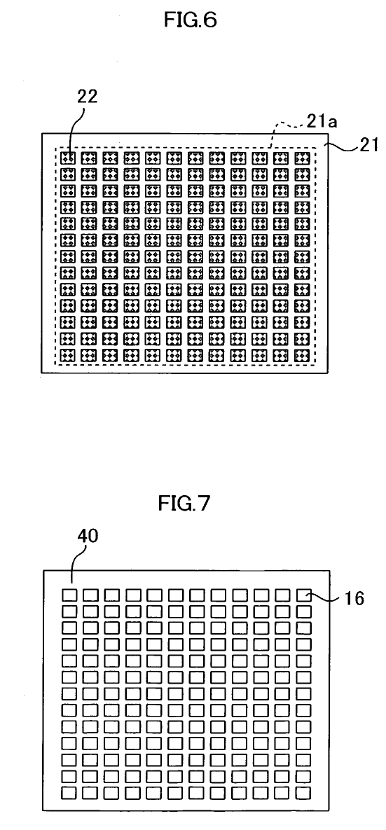

FIG. 6 is a plan view of a two-dimensional thermal head 21 having a plurality of heating elements 22 arranged two-dimensionally, for example, in a matrix in a heating region 21a. The use of the two-dimensional thermal head 21 enables a deposition material to be deposited easily and effectively in a short time. The heating region 21a has an area covering a nearly entire display region to be formed by organic EL elements, and is constituted by a plurality of heating elements 22 corresponding to the respective organic EL elements.

FIG. 7 is a plan view of an organic EL display panel 40 having an array of light-emitting portions 16 corresponding to the respective heating elements 22 of the two-dimensional thermal head 21. The organic EL display panel 40 is capable of displaying a full color image by the red (R), green (G) and blue (B) light-emitting portions 16 (organic EL elements) arranged on the substrate 4 of glass in a matrix and in a predetermined repetitive order. The heating elements 22 of the two-dimensional thermal head 21 are in a one-to-one correspondence with the light-emitting portions 16 to be formed.

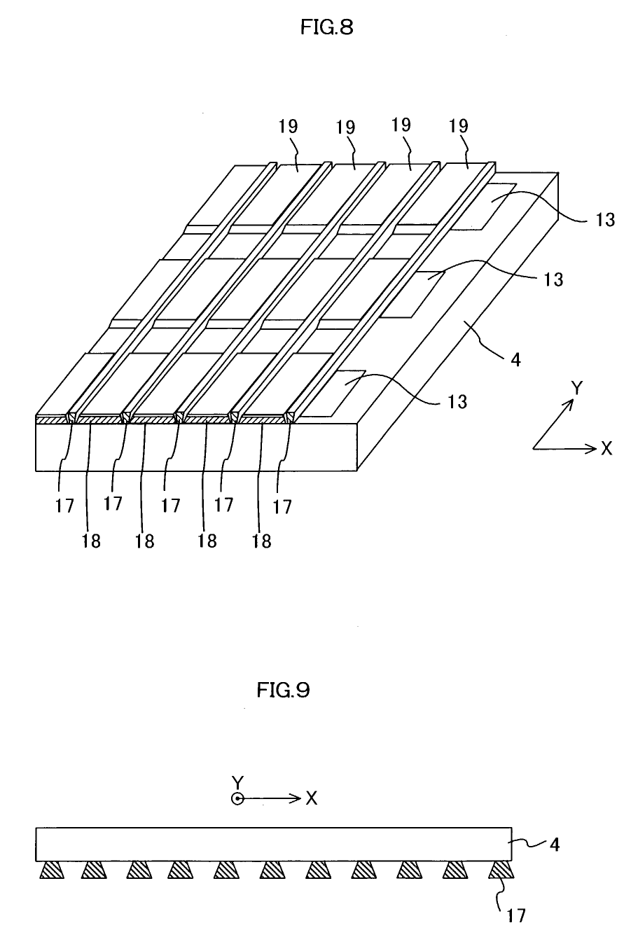

FIG. 8 is a schematic partial perspective view enlargedly showing one example of the organic EL display panel 40. On the transparent display panel substrate 4 of the organic EL display panel 40, there are formed respective layers of transparent electrodes 13, for example, of indium tin oxide (hereinafter simply referred to as ITO), which are arranged in stripes parallel to each other. Barrier ribs 17 are provided on the substrate 4 so as to be parallel to each other and orthogonal to the transparent electrodes 13. Further, the barrier ribs 17 are formed to protrude from the substrate 4, and are arranged such that parts of transparent electrodes 13 are exposed partly. The barrier ribs 17 function as a support member (i.e., support mechanism) formed on the substrate 4, for causing the deposition material sheet (not shown) and the substrate 4 to be opposed to each other with a space therebetween. In the present embodiment, a simple matrix type organic EL display panel is provided. The stacks of organic layers 18 are deposited on the exposed parts of the stripe-shaped transparent electrodes 13, and stripe-shaped metal electrodes 19 are formed on the organic layers 18 crosswise to the transparent electrodes 13 to bridge the organic layers 18 respectively. Furthermore, it should be noted that the present invention can also be applied to the manufacturing of an active matrix type organic EL display panel, for example, by using a substrate formed thereon with active devices, such as TFT (thin-film transistor), connected to respective organic EL elements.

In each area sandwiched between adjacent two of the barrier ribs 17, at least one organic layer 18 is formed as a stack on each transparent electrode 13. The organic layer 18 may be formed by a single light-emitting layer, or by multiple layers of a hole transport layer, an electron transport layer, and the light-emitting layer, or of an electron transport layer or a hole transport layer, in addition to the light-emitting layer. Each barrier rib 17 may be formed between transparent electrodes 13 in a manner extending in parallel with the transparent electrodes 13. Alternatively, the barrier ribs 17 may be formed in a manner enclosing each pixel.

FIG. 9 is a cross-sectional view schematically showing a display panel substrate in the embodiment. As shown in FIG. 9, each barrier rib 17 may be formed on the display panel substrate 4 to have an overhung shape such as a reverse tapered shape or a T shape in cross section. The barrier ribs 17 serve as separators in the process of depositing layers on the display panel substrate. More specifically, the existence of each barrier ribs 17 prevents deposited material from spreading over an adjacent pixel, to thereby enable selective deposition.

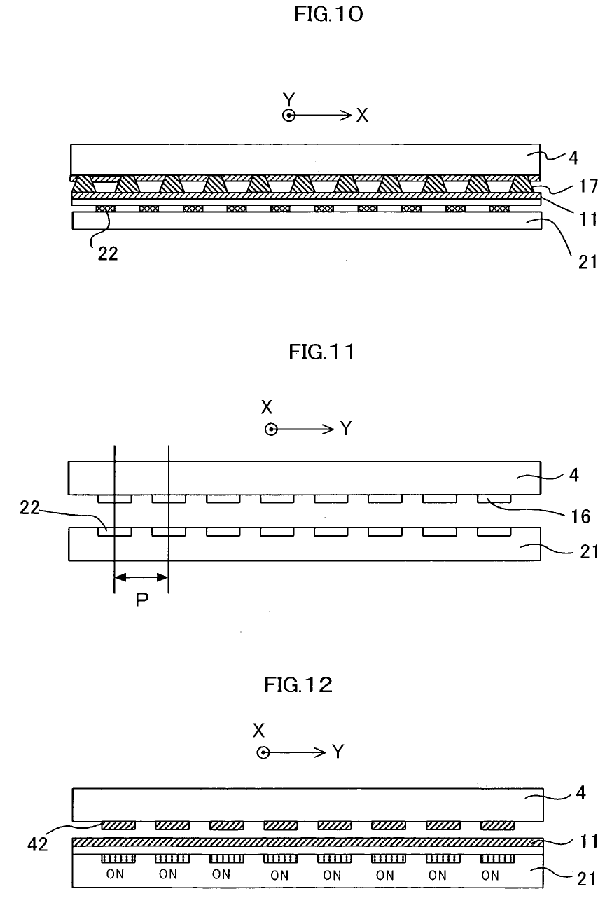

FIG. 10 is a cross-sectional view schematically showing a stacked state of the display panel substrate 4, the deposition material sheet 11 and the thermal head 21 in a step of manufacturing method of the embodiment. When the heating elements 22 of the thermal head 21 are pressed against the barrier ribs 17 on the display panel substrate 4 via the deposition material sheet 11, as shown in FIG. 10, the space or distance between the substrate 4 and the deposition material sheet 11 is made constant, which ensures stable deposition.

FIG. 11 is a cross-sectional view schematically showing a relationship between the display panel substrate 4 having an array of light-emitting portions 16 and the thermal head 21 of the embodiment. As shown in FIG. 11, both the heating elements 22 of the thermal head 21 and the transparent electrodes 13 of the respective pixels on the substrate 4 are arranged at intervals of an identical pitch P. So long as the thermal head is a two-dimensional type, the pitch P may be set to be identical in the X and Y directions.

Next, description will be given of a process of manufacturing the display panel of an organic EL multi-color display, in which deposition is carried out by using a two-dimensional thermal head 21.

First, an ITO transparent layer is deposited on a glass substrate with a constant thickness by sputtering or the like and then is patterned into stripe electrodes by means of etching or the like. As a result, on the glass substrate, the transparent ITO electrodes (anodes) for B, G, and R are previously formed to be extended in parallel to each other. After that, a plurality of barrier ribs, made of a photosensitive polyimide or the like, may be provided at the same pitch in parallel to each other so as to be orthogonal to the transparent electrode lines.

Next, as shown in FIG. 12, hole transport layers 42 are simultaneously formed on transparent electrodes 13 by vacuum deposition. A predetermined deposition material sheet 11 is placed below the display panel substrate 4 such that the sheet 11 is spaced apart from the substrate in the gravitation direction. The two-dimensional thermal head 21 is placed below the deposition material sheet 11 so as to come into contact therewith in the gravitation direction. By heating the predetermined deposition material sheet 11 with all the heating elements 22, an organic material is evaporated to be deposited onto hole transport layers 42 on the display panel substrate 4. If selective deposition is desired, a metal mask having necessary openings for the deposition may be used between the substrate 4 and the deposition material sheet 11. The metal mask is a flat plate formed with a plurality of openings corresponding to respective organic EL elements to be formed.

Then, as shown in FIG. 13, layers of a light-emitting material R for red emission are selectively deposited. In this case, a predetermined deposition material sheet 11R coated with the light-emitting material R for red emission is placed below the display panel substrate 4 such that the sheet 11R is spaced apart from the substrate 4, and the thermal head having the heating elements 22 corresponding to the respective pixels is positioned under the deposition material sheet 11R in contact therewith. Then, heating elements 22R corresponding to respective red pixels are switched ON to be heated and the others OFF, whereby the light-emitting material R can be deposited to form only the red pixels. The deposition material sheet 11R and the substrate 4 are positioned close to each other, so that it is possible to carry out the selective deposition of the light-emitting material R without spoiling pixels of the other colors.

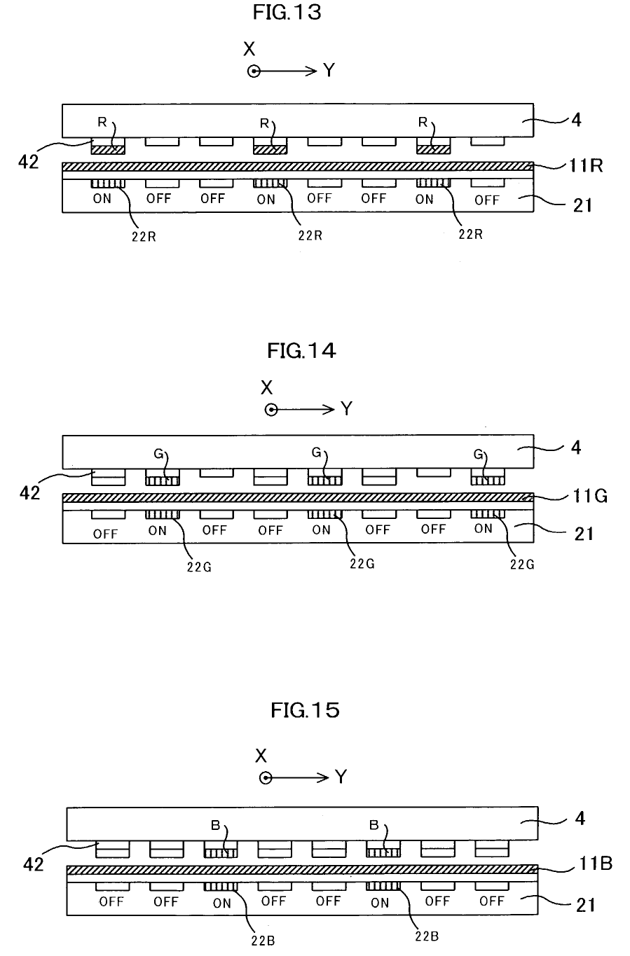

Then, as shown in FIG. 14, a light-emitting material G for green emission is selectively deposited. In this case, a predetermined deposition material sheet 11G coated with the light-emitting material G for green emission is placed below the display panel substrate 4 such that the sheet 11G is spaced apart from the substrate 4, and the thermal head having the heating elements 22 corresponding to the respective pixels is positioned under the deposition material sheet 11G. Then, heating elements 22G corresponding to respective green pixels are switched ON to be heated and the others OFF, whereby the light-emitting material G can be deposited to form the green pixels.

Then, as shown in FIG. 15, a light-emitting material B for blue emission is deposited. In this case, a predetermined deposition material sheet 11B coated with the light-emitting material B for blue emission is placed below the substrate 4 such that the sheet 11B is spaced apart from the substrate 4, and the thermal head having the heating elements corresponding to the respective pixels is positioned under the deposition material sheet 11B. Then, heating elements 22B corresponding to respective blue pixels are switched ON to be heated and the others OFF, whereby the light-emitting material B can be deposited to form the blue pixels.

As seen from FIGS. 12-15, the process of manufacturing the display panel of an organic EL multi-color display may include a step of collectively depositing an organic material common to the organic EL elements for colors of light emission at an identical thickness (FIG. 12). Furthermore the manufacturing process also may include steps of respectively depositing organic materials as layers having different thicknesses corresponding to colors of light emission of said organic EL elements (FIGS. 13-15).

In addition, the manufacturing process also may include a step of collectively depositing an identical organic material common to said organic EL elements for colors of light emission (FIG. 12), and steps of respectively depositing different organic materials corresponding to colors of light emission of said organic EL elements (FIGS. 13-15).

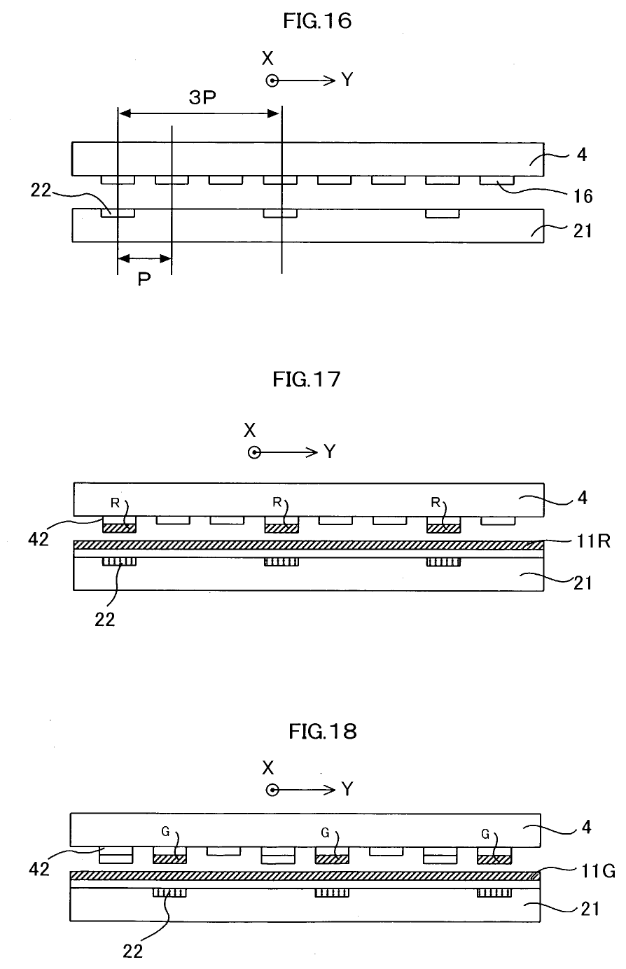

FIG. 16 shows a cross-sectional view of another embodiment which schematically shows a relationship between the display panel substrate 4 having an array of light-emitting portions 16 and the thermal head 21. As shown in FIG. 16, the heating elements 22 of the thermal head 21 may be arranged at intervals of integer times of the pixel pitch P of the organic EL elements to be formed (i.e., at intervals of n x P (e.g., 3P)). In the present embodiment, the number of the heating elements is reduced to be sparser than that of the embodiment as shown in FIG. 11, as differently from the embodiment shown in FIG. 6 in which the heating elements 22 of the thermal head 21 are arranged in a one-to-one correspondence with the light-emitting portions 16 (organic EL elements). In short, in the FIG. 16 embodiment, the heating elements 22 of the thermal head can be arranged at intervals of the pixel pitch of organic EL elements to be selected for deposition.

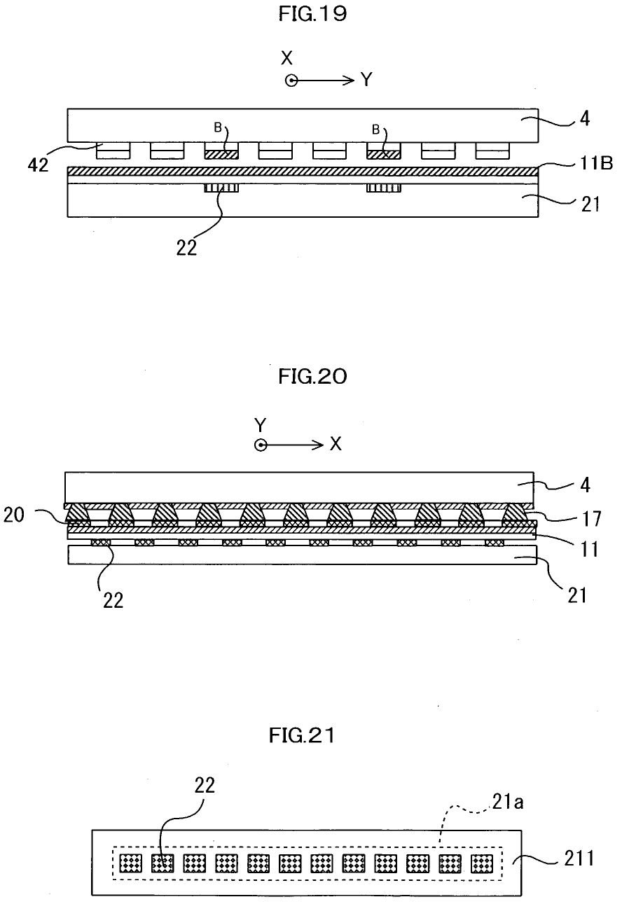

As shown in FIGS. 17 to 19, the use of this thermal head having a reduced number of heating elements also makes it possible to deposit a selected one of the light-emitting materials R, G and B without spoiling pixels of the other colors. A deposition material sheet coated with the light-emitting material R and a display panel substrate are positioned close to each other, which enables selective deposition. The steps illustrated in FIGS. 17 to 19 are identical to that illustrated in FIGS. 13 to 15 respectively except that the thermal head 21 and the substrate 4 are moved relatively to each other by the distance of a predetermined pitch in place of switching of the heating elements 22R, 22G and 22B for the respective colors R, G and B.

Further, in another embodiment, a process for selective deposition is employed which is identical to that illustrated in FIG. 10 except that a metal mask 20 is interposed between the deposition material sheet 11 and the barrier ribs 17 on the substrate 4 as shown in FIG. 20.

In still another embodiment, as shown in FIG. 21, the thermal head may be a one-dimensional thermal head 211 having heating elements 22 arranged one-dimensionally (e.g., linearly). A heating region 21a is smaller in width than the display region to be formed by the organic EL elements to be formed on the display panel substrate 4, and extends over a portion of the display region. The area of the heating region 21a is smaller than that of the display region. It suffices that the heating region 21a can cover at least part of the display region with a space maintained between the display region and the heating region 21a. The one-dimensional thermal head 211 may be combined with a metal mask for deposition.

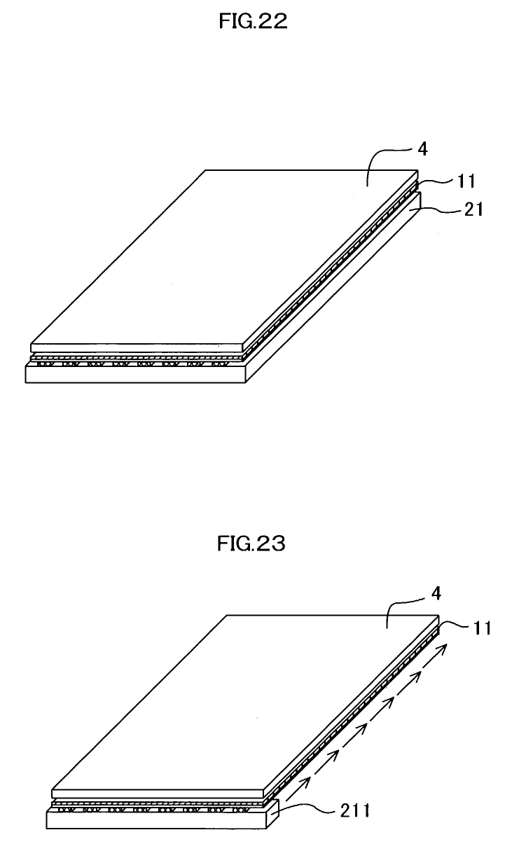

In the case of the two-dimensional thermal head 21 being used, as shown in FIG. 22, the deposition material sheet 11 is sandwiched between the display panel substrate 4 and the thermal head 21, whereas in the case of the FIG. 21 one-dimensional thermal head 211 being used, as shown in FIG. 23, the deposition material sheet 11 is held apart from the substrate 4, and the heat-resistant sheet-side surface of the deposition material sheet 11 is relatively scanned by the heating elements 22 arranged one-dimensionally.

In the latter case, when the one-dimensional thermal head 211 moves to a predetermined position on the deposition material sheet 11 and heats the deposition material sheet 11 by heating elements 22 corresponding to desired pixels, an organic material is evaporated to be partly deposited onto desired portions of the display panel substrate 4. Then, the substrate 4 or the thermal head 211 is relatively moved sequentially to predetermined-positions, as shown in FIG. 23, while being stopped at each of the predetermined positions for deposition, until layers are formed on the entire surface of the substrate. In this way, the vacuum deposition is repeatedly preformed.

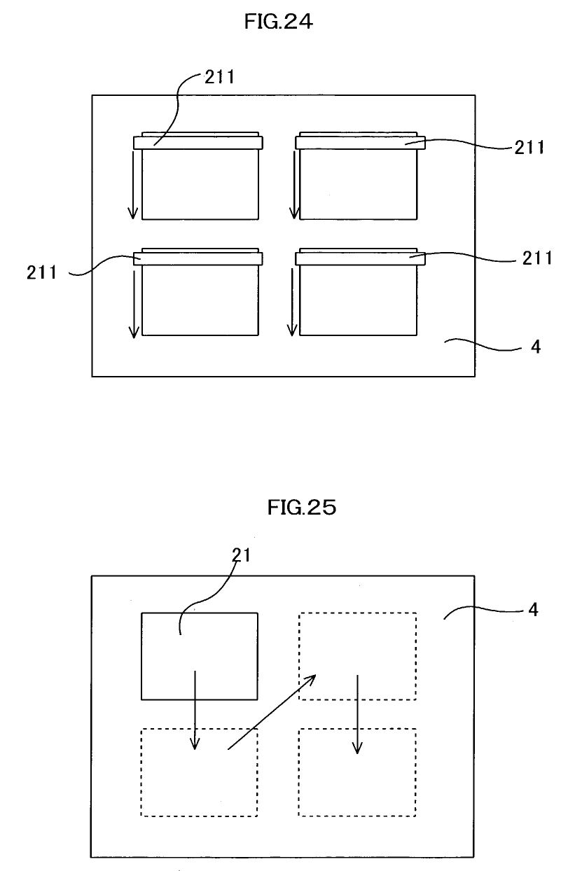

When a display panel substrate 4 for manufacturing a plurality of display panels is used, a method with enhanced deposition efficiency can be employed in which a plurality of one-dimensional thermal heads 211 are positioned along respective display regions to be formed on the substrate 4 and moved relatively to the respective display regions, as shown in FIG. 24. Further, when the two-dimensional thermal head 21 is used, it is possible to enhance deposition efficiency by positioning the thermal head 21 at a location facing one of display regions to be formed on the substrate 4 for manufacturing a plurality of display panels, to perform the deposition, and sequentially moving the thermal head 21 relative to the substrate 4, one display region to another, as shown in FIG. 25. As described above, layers can be efficiently deposited by using the thermal head having the heating elements arranged one-dimensionally or two-dimensionally and having a predetermined area smaller than the area of the substrate 4. This method is effective in manufacturing a plurality of panels by cutting these from a large display panel substrate. Further, since layers can be formed on limited portions of a single display panel substrate, it is possible to reduce sizes of a thermal head and heating elements thereon, a metal mask, a deposition material sheet, and so forth, which contributes to making the apparatus less expensive and improving the manufacturing efficiency.

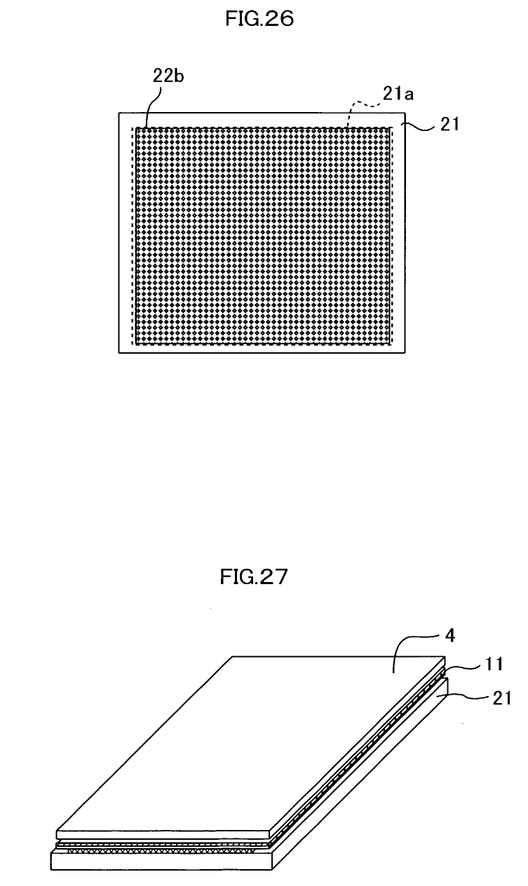

A further embodiment is distinguished from the above embodiments in each of which the heating region of a thermal head is constituted by a plurality of heating elements corresponding to respective organic EL elements, in that, as shown in FIG. 26, a heating region 21a of a thermal head 21 having an area covering a nearly entire display region to be formed by organic EL elements can be formed by a single heating element 22b corresponding to a plurality of organic EL elements to be formed. As shown in FIG. 27, the present embodiment makes it possible to form predetermined deposition material layers on the entire surface of a display panel substrate 4 in a deposition process. Also in this case, it is possible to enhance deposition efficiency by positioning the thermal head 21 at a location facing a display region to be formed on the substrate 4 for manufacturing a plurality of display panels, to perform the deposition, and sequentially moving the thermal head 21 relative to the substrate 4, one display region to another, as shown in FIG. 25.

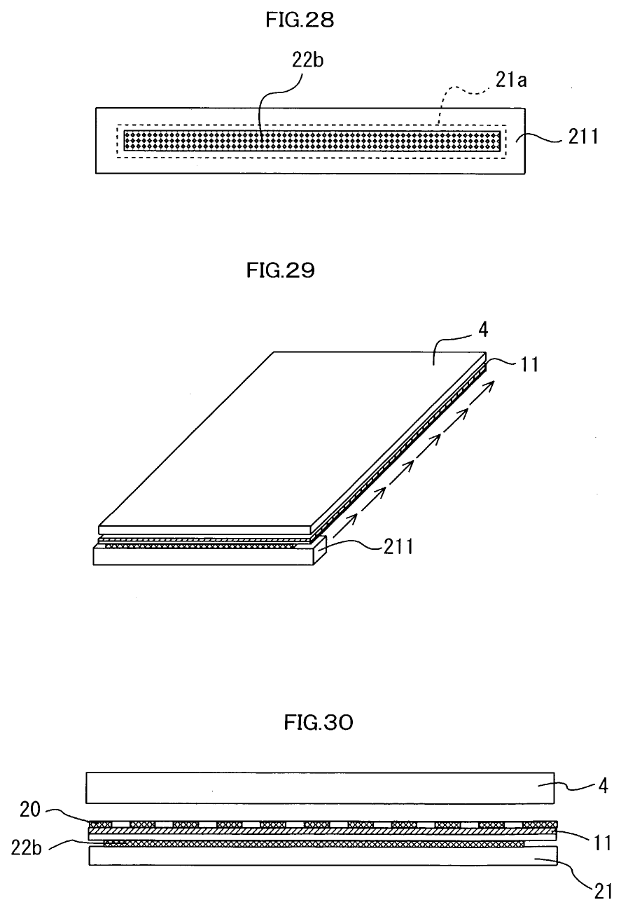

When the one-dimensional thermal head 211 is employed, the heating region 21a can be formed, as shown in FIG. 28, such that the heating region 21a has a smaller width than that of the display region of the organic EL elements and extends over a portion of the display region, and that the area thereof is smaller than that of the display region. According to this embodiment, the display panel substrate or the thermal head 211 is relatively moved to predetermined positions sequentially as shown in FIG. 29 while being stopped at each of the predetermined positions to partially deposit a deposition material onto the substrate, whereby layers are formed on the entire surface of the substrate. In the present embodiment as well, it is possible to improve deposition efficiency by positioning a plurality of one-dimensional thermal heads 211 along respective display regions to be formed on the substrate 4 for manufacturing a plurality of panels, and moving the one-dimensional thermal heads 211 relatively to the respective display regions to perform the deposition, as shown in FIG. 24.

In these embodiments as well, similarly to configuration shown in FIG. 2, the manufacturing apparatus is provided with a power unit 30, a temperature-detecting section 31, and a temperature control section 32.

In still another embodiment, as shown in FIG. 30, there is employed a process which is identical to that illustrated in FIG. 27 except that a metal mask 20 is arranged between a deposition material sheet 11 and a display panel substrate 4, for selective deposition in correspondence with each organic EL element. In this embodiment, organic EL elements can be formed on a color-by-color basis by relative translation of the metal mask 20. In this case, barrier ribs can be formed on the substrate 4 similarly to the aforementioned embodiments.

According to the invention, it is possible to manufacture efficiently a high precise organic EL display panel in less expensive manner.

It is understood that the foregoing description and accompanying drawings set forth the preferred embodiments of the invention at the present time. Various modifications, additions and alternative designs will, of course, become apparent to those skilled in the art in light of the foregoing teachings without departing from the spirit and scope of the disclosed invention. Thus, it should be appreciated that the invention is not limited to the disclosed embodiments but may be practiced within the full scope of the appended claims.

This application is based on a Japanese Patent Application No. 2002-25691 which is hereby incorporated by reference.

What is claimed is:

1. A manufacturing apparatus for manufacturing an organic electroluminescence display panel that has a plurality of organic electroluminescence elements arranged on a substrate, each of the organic electroluminescence elements being formed of at least one organic layer each of which contains a light-emitting layer sandwiched by a pair of electrodes,
the manufacturing apparatus comprising:
one or more heating elements having a heating region covering at least part of a display region to be constituted by a plurality of organic electroluminescence elements to be formed on the substrate, with a space maintained between the display region and the heating region;
a deposition material sheet formed of a heat-resistant sheet having one main surface thereof coated with a thin layer of a deposition material and another main surface thereof in contact with the heating elements; and
a support mechanism for causing the thin layer on said deposition material sheet and the substrate to be opposed to each other with a space maintained therebetween.

2. A manufacturing apparatus according to claim 1, wherein said heating region has an area covering substantially said display region.

3. A manufacturing apparatus according to claim 1, wherein said heating region has a width smaller than that of said display region so as to extend over said display region and having an area smaller than that of said display region.

4. A manufacturing apparatus according to claim 1, further comprising at least one active device connected to said organic electroluminescence element and formed on said substrate.

5. A manufacturing apparatus according to claim 2, wherein said heating region is constituted by a plurality of heating elements corresponding to said organic electroluminescence elements to be formed.

6. A manufacturing apparatus according to claim 5, wherein said heating elements are arranged one-dimensionally.

7. A manufacturing apparatus according to claim 5, wherein said heating elements are arranged two-dimensionally.

8. A manufacturing apparatus according to claim 5, wherein said heating elements are in a one-to-one correspondence with said light-emitting portions.

9. A manufacturing apparatus according to claim 8, wherein said heating elements and said organic electroluminescence elements to be formed are arranged at intervals of an identical pitch.

10. A manufacturing apparatus according to claim 8, wherein said heating elements are arranged at intervals of integer times of a pixel pitch of said organic electroluminescence elements to be formed.

11. A manufacturing apparatus according to claim 5, wherein said heating elements are formed as protrusions.

12. A manufacturing apparatus according to claim 5, further comprising a power unit connected to said heating elements for selectively energizing said heating elements to evaporate the deposition material.

13. A manufacturing apparatus according to claim 12, further comprising a temperature control system connected to said heating elements for controlling the temperature of said heating elements.

14. A manufacturing apparatus according to claim 13, wherein said temperature control system comprises a temperature-detecting section for detecting said heating elements so as to control the temperature of said heating elements according to the detected temperature.

15. A manufacturing apparatus according to claim 13, wherein said temperature control system controls the temperature of said heating elements such that uniformity in temperature of said heating elements is maintained.

16. A manufacturing apparatus according to claim 13, wherein said temperature control system controls the temperature of said heating elements such that individual temperature of said heating elements is differ from each other.

17. A manufacturing apparatus according to claim 2, wherein said heating region is constituted by a single heating element corresponding to said organic electroluminescence elements to be formed.

18. A manufacturing apparatus according to claim 17, wherein a power unit connected to said single heating element for energizing said heating elements to evaporate the deposition material.

19. A manufacturing apparatus according to claim 18, wherein further comprising a temperature control system connected to said single heating element for controlling the temperature of said heating element.

20. A manufacturing apparatus according to claim 19, wherein said temperature control system comprises a temperature-detecting section for detecting said single heating element so as to control the temperature of said heating element according to the detected temperature.

21. A manufacturing apparatus according to claim 1, wherein the heating elements is placed below said substrate in a gravitation direction.

22. A manufacturing apparatus according to claim 1, further comprising a translation drive apparatus for causing translation of said heating elements and said substrate relative to each other in parallel.

23. A manufacturing apparatus according to claim 1, wherein said heating elements are grouped as plural sets and operated so that the deposition material is partly deposited on said substrate per set.

24. A manufacturing apparatus according to claim 1, wherein said support mechanism comprising a support member formed on said substrate.

25. A manufacturing apparatus according to claim 1, further comprising a metal mask having a plurality of openings corresponding to said organic electroluminescence elements and placed between said substrate and said deposition material sheet.

26. A manufacturing apparatus according to claim 1, wherein the deposition material is an organic material or an electrode material.

27. A method of manufacturing an organic electroluminescence display panel that has a plurality of organic electroluminescence elements arranged on a substrate, each of the organic electroluminescence elements being formed of at least one organic layer each of which contains a light-emitting layer sandwiched by a pair of electrodes,
the method comprising the steps of:
positioning a deposition material sheet formed of a heat-resistant sheet having one main surface thereof coated with a thin layer of a deposition material such that another main surface of the deposition material sheet is brought into contact with one or more heating elements having a heating region corresponding to at least part of a display region to be constituted by a plurality of organic electroluminescence elements to be formed on the substrate;
causing the thin layer on the deposition material sheet and the substrate to be opposed to each other with a space maintained therebetween; and
heating the deposition material sheet by energizing the heating region, thereby evaporating the deposition material to perform deposition on the substrate.

28. A method according to claim 27, wherein said heating region has an area covering substantially said display region.

29. A method according to claim 27, wherein said heating region has a width smaller than that of said display region so as to extend over said display region and having an area smaller than that of said display region, and said method further comprising a step of vacuum deposition for partly depositing the deposition material on said substrate in a manner that said vacuum deposition is repeatedly preformed for said substrate.

30. A method according to claim 28, wherein said heating region is constituted by a plurality of heating elements corresponding to said organic electroluminescence elements to be formed.

31. A method according to claim 30, wherein said heating elements are arranged one-dimensionally.

32. A method according to claim 30, wherein said heating elements are arranged two-dimensionally.

33. A method according to claim 30, wherein said heating elements are in a one-to-one correspondence with said light-emitting portions.

34. A method according to claim 33, wherein said heating elements and said organic electroluminescence elements to be formed are arranged at intervals of an identical pitch.

35. A method according to claim 33, wherein said heating elements are arranged at intervals of integer times of a pixel pitch of said organic electroluminescence elements to be formed.

36. A method according to claim 30, wherein said heating elements are formed as protrusions.

37. A method according to claim 30, further comprising a step of selectively energizing and heating said heating elements to evaporate the deposition material.

38. A method according to claim 37, wherein said heating elements are detected in temperature so that the temperature of said heating elements are controlled according to the detected temperature.

39. A method according to claim 30, wherein temperature of said heating elements is controlled such that uniformity in temperature of said heating elements is maintained.

40. A method according to claim 30, wherein temperature of said heating elements is controlled such that individual temperature of said heating elements is differ from each other.

41. A method according to claim 28, wherein said heating region is constituted by a single heating element corresponding to said organic electroluminescence elements to be formed.

42. A method according to claim 41, wherein said heating element is selectively energized and heated to evaporate the deposition material.

43. A method according to claim 42, wherein said heating element is detected in temperature so that the temperature of said heating element is controlled according to the detected temperature.

44. A method according to claim 27, wherein the heating elements is placed below said substrate in a gravitation direction.

45. A method according to claim 27, wherein said heating elements and said substrate are moves in translation relative to each other in parallel.

46. A method according to claim 45, wherein said heating elements are grouped as plural sets and operated so that the deposition material is partly deposited on said substrate per set.

47. A method according to claim 27, further comprising a step of forming a support member on said substrate to separate said deposition material sheet and said substrate with a space.

48. A method according to claim 27, further comprising a step of providing a metal mask having a plurality of openings corresponding to said organic electroluminescence elements and placed between said substrate and said deposition material sheet.

49. A method according to claim 27, wherein the deposition material is an organic material or an electrode material.

50. A method according to claim 27, wherein said step of evaporating the deposition material to perform deposition on the substrate, comprises a step of collectively depositing an organic material common to said organic electroluminescence elements for colors of light emission at an identical thickness, and steps of respectively depositing organic materials as layers having different thicknesses corresponding to colors of light emission of said organic electroluminescence elements.

51. A method according to claim 27, wherein said step of evaporating the deposition material to perform deposition on the substrate, comprises a step of collectively depositing an identical organic material common to said organic electroluminescence elements for colors of light emission, and steps of respectively depositing different organic materials corresponding to colors of light emission of said organic electroluminescence elements.
